(19) United States
(12) Patent Application Publication
(10) Pub. No.: US 2008/0315297 A1
(43) Pub. Date: Dec. 25, 2008

(54) SEMICONDUCTOR DEVICE

(75) Inventors: Masakatsu TAKASHITA, Kawasaki-shi (JP); Yasuto SUMI, Himeji-shi (JP); Masaru IZUMISAWA, Himeji-shi (JP); Hiroshi OHTA, Tokyo (JP); Wataru SAITO, Kawasaki-shi (JP); Syotaro ONO, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/144,985

(22) Filed: Jun. 24, 2008

(30) Foreign Application Priority Data
Jun. 25, 2007 (JP) 2007-165797

(51) Int. Cl. H01L 29/78

(52) U.S. Cl. 257/328; 257/E29.256

(57) ABSTRACT

There is provided a semiconductor device having a drift layer with a pillar structure including first semiconductor layer portions of the first conduction type and second semiconductor layer portions of the second conduction type formed in pillars alternately and periodically on a semiconductor substrate. A device region includes a plurality of arrayed transistors composed of the first semiconductor layer portions and the second semiconductor layer portions. A terminal region is formed at the periphery of the device region without the transistors formed therein. The drift layer in the terminal region has a carrier lifetime lower than ⅕ the carrier lifetime in the drift layer in the device region.

### CROSS-REFERENCE TO RELATED APPLICATION

This application is based upon and claims the benefit of priority from prior Japanese Patent Application No. 2007-165797, filed on Jun. 25, 2007, the entire contents of which are incorporated herein by reference.

### BACKGROUND OF THE INVENTION

1. Field of the Invention

The present invention relates to a semiconductor device, and more particularly to a power semiconductor device with a high-breakdown voltage structure.

2. Description of the Related Art

In response to the needs in the field of recent power electronics for downsized high-performance power supplies, effort is put into improving performances to achieve high-breakdown voltage/large-current and low-loss/high-speed power semiconductor devices. Of those, a power MOSFET (Metal Oxide Semiconductor Field Effect Transistor) has a high-speed switching performance and becomes established as a key device in the field of switching power supplies and so forth.

The MOSFET is a majority carrier device, which is advantageous because it has no minority-carrier storage time and capable of fast switching. On the other hand, as it has no conductivity modulation, it is more disadvantageous in high-breakdown voltage devices from the viewpoint of the on-resistance than bipolar devices such as an IGBT (Insulated Gate Bipolar Transistor). This is caused by the fact that a thicker N-type base layer and a lower impurity concentration are required to achieve a high breakdown voltage in the MOSFET and correspondingly a higher-breakdown voltage device increases the on-resistance of the MOSFET.

The on-resistance of the power MOSFET greatly depends on the electric resistance in a conduction layer (N-type drift layer). The impurity concentration that determines the electric resistance in the N-type drift layer corresponds to the breakdown voltage across a PN junction formed between a P-type base and the N-type drift layer and accordingly has an upper limit. Therefore, there is a tradeoff between the device breakdown voltage and the on-resistance. An improvement in the tradeoff is important for low-power consumption devices. The tradeoff has a limit determined by the material of the device and thus surmounting the tradeoff leads to the realization of low-on-resistance devices that can exceed existing power devices.

To solve the problem, there is known a structure referred to as a superjunction structure, which includes a P-type drift layer (P-type pillar layer) buried in an N-type drift layer (N-type pillar layer). Specifically, JP 2000-40822A and JP 2001-168036A disclose semiconductor devices with a structure formed of parallel PN layers including impurity concentration-increased N-type regions and P-type regions arranged alternately as a drift layer, which can be depleted in the off-state to retain the breakdown voltage.

There is disclosed a method of forming the N-type pillar layer and the P-type pillar layer in the semiconductor devices described in the above patent publications. The method comprises forming an N-type semiconductor layer by epitaxial growth; forming a resist pattern; forming a P-type semiconductor region by implantation of ions of B or the like; removing the resist pattern; repeating such a series of processes; and then forming P-type pillar layer portions and N-type pillar layer portions alternately.

The semiconductor device including alternately formed P-type pillar layer portions and N-type pillar layer portions has a device region with transistors formed therein, and a terminal region surrounding the periphery without transistors formed therein. The P-type pillar layer and the N-type pillar layer may be formed in the terminal region. In this case, if the quantity of the impurity in the P-type pillar layer is equal to the quantity of the impurity in the N-type pillar layer, the breakdown voltage in the terminal region is made lower than that in the device region. This causes a problem because the entire semiconductor device may be broken down.

On the other hand, the P-type pillar layer portions and the N-type pillar layer portions may be formed alternately only in the device region while the P-type pillar layer portions and the N-type pillar layer portions may not be formed alternately in the terminal region. In such the semiconductor device, the terminal region is formed of a high-resistance layer to enhance the breakdown voltage in the terminal region. In this case, if only the breakdown voltage in the terminal region is enhanced higher than that in the device region, the carrier excessively stored in the terminal region can not be discharged sufficiently on reverse recovery of the internal diode in the transistor in the device region. Also in this case, the entire semiconductor device may be broken down.

### SUMMARY OF THE INVENTION

In one aspect the present invention provides a semiconductor device having a drift layer with a pillar structure including first semiconductor layer portions of the first conduction type and second semiconductor layer portions of the second conduction type formed in pillars alternately and periodically on a semiconductor substrate, the device comprising: a device region including a plurality of transistors composed of the first semiconductor layer portions and the second semiconductor layer portions and arrayed in the central area of the semiconductor device; and a terminal region formed at the periphery of the device region without the transistors formed therein, wherein the drift layer in the terminal region has a resistance controlled higher than the resistance of the drift layer in the device region and higher than the resistance determined by an impurity concentration.

In one aspect the present invention provides a semiconductor device having a drift layer with a pillar structure including first semiconductor layer portions of the first conduction type and second semiconductor layer portions of the second conduction type formed in pillars alternately and periodically on a semiconductor substrate, the device comprising: a device region including a plurality of transistors composed of the first semiconductor layer portions and the second semiconductor layer portions and arrayed in the central area of the semiconductor device; and a terminal region formed at the periphery of the device region without the transistors formed therein, wherein the drift layer in the terminal region has a carrier lifetime controlled lower than ⅕ the carrier lifetime in the drift layer in the device region.

### BRIEF DESCRIPTION OF THE DRAWINGS

FIG. 1 shows a structural cross-sectional view of a semiconductor device in a first embodiment.

FIG. 2 shows a structural cross-sectional view of a semiconductor device in a second embodiment.

FIG. 3 shows a first process step in the present embodiment.

FIG. 4 shows a second process step in the present embodiment.

FIG. 5 shows a third process step in the present embodiment.

FIG. 6 shows a fourth process step in the present embodiment.

FIG. 7 shows a fifth process step in the present embodiment.

FIG. 8 shows a sixth process step in the present embodiment.

### DETAILED DESCRIPTION OF THE EMBODIMENTS

### First Embodiment

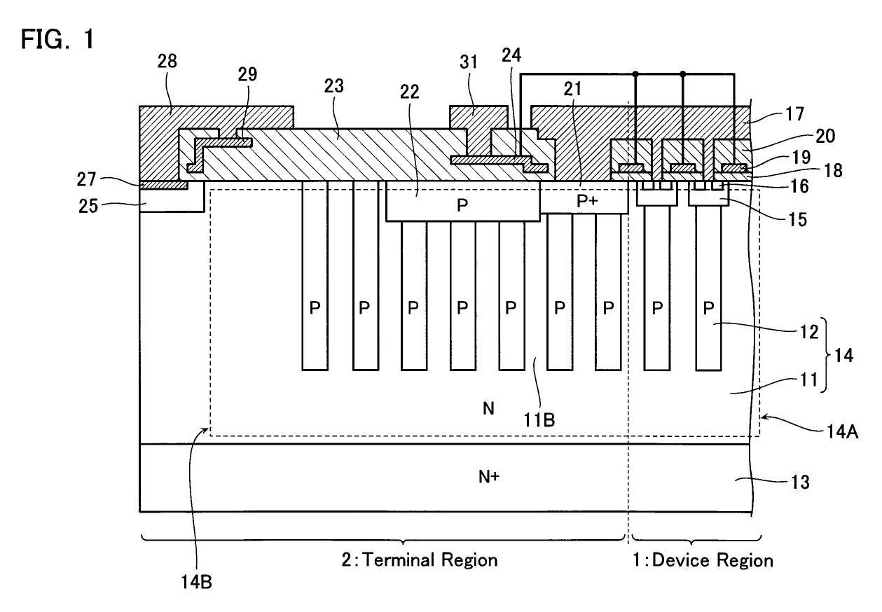

One embodiment in the present invention will now be described below. A semiconductor device in the present embodiment is shown in FIG. 1. The semiconductor device in the present embodiment is a power semiconductor device, which comprises a device region 1 and a terminal region 2.

A transistor formed in the device region 1 has a superjunction structure, which includes an N-type drift layer 11, and a plurality of P-type pillar layer portions 12 formed in the N-type drift layer 11. The N-type drift layer 11 has one surface (the lower surface in FIG. 1), on which an N⁺-type drain layer 13 is formed with a higher impurity concentration than the N-type drift layer 11. A drain electrode, not shown, is formed on the surface of the N⁺-type drain layer 13. In the present embodiment, a drift layer 14 includes the N-type drift layer 11 and the P-type pillar layer 12, and the drift layer 14 has a drift layer 14A formed in the device region 1 and a drift layer 14B formed in the terminal region 2. The N-type drift layer 11 and the N⁺-type drain layer 13 can be formed through a method of diffusing an impurity into one surface of the N-type drift layer 11 or a method of crystal-growing the N-type drift layer 11 on the N⁺-type drain layer 13 that serves as a substrate.

On the other surface of the N-type drift layer 11, without the N⁺-type drain layer 13 formed therein, the P-type pillar layer portions 12 are formed periodically as described above. An N-type drift layer portion 11 formed between a P-type pillar layer portion 12 and an adjacent P-type pillar layer portion 12 is specially referred to as an N-type drift layer portion 11B. In a region spread over the surface of the P-type pillar layer portion 12, a P-type base layer 15 is formed through ion implantation. The P-type base layer 15 is formed in a stripe extending in the direction normal to the drawing. In the surface of each P-type base layer 15 thus formed, two N-type source layers 16 are formed extending in the direction normal to the drawing.

Further, a gate insulator 18 is formed on the surface of the N-type drift layer 11 sandwiched between a P-type base layer 15 and an adjacent P-type base layer 15, that is, a surface region between an N-type source layer 16 and an adjacent N-type source layer 16 with the N-type drift layer portion 11 sandwiched between the P-type base layers 15. The gate insulator 18 is composed of silicon oxide with a thickness of about 0.1 [μs], for example. Further, a gate electrode 19 is formed on the gate insulator 18 and the gate electrode 19 is connected to other gate electrodes. An interlayer insulator 20 is formed on the gate electrodes 19.

In a region sandwiched between the gate electrode 19 and the gate electrode 19, a source electrode 17 is formed in contact with a P-type base layer 15 and two N-type source layers 16 formed in this P-type base layer 15. The source electrode 17 is formed to cover the interlayer insulator 20 and is connected to other source electrodes. The source electrode 17 is electrically insulated from the gate electrode 19 with the interlayer insulator 20 interposed therebetween.

Also in the terminal region 2, on the other hand, the N-type drift layer 11 (including the N-type pillar layer) and the P-type pillar layer portions 12 are formed to configure a superjunction structure.

In the terminal region 2, a P⁺-type guard ring layer 21 is formed through ion implantation in the surface near the device region 1 with the N-type drift layer 11 and the P-type pillar layer 12 formed therein. The surface of the P⁺-type guard ring layer 21 comes in contact with the source electrode 17.

In the terminal region 2, a P-type resurf layer 22 is formed in the surface, adjacent to the P⁺-type guard ring layer 21 and extending to the direction opposite to the device region 1.

In the terminal region 2, an interlayer insulator 23 is formed over the surfaces of the P-type resurf layer 22, the N-type drift layer 11 and the P-type pillar layer 12. A field plate 24 for connection to the gate electrode 19 is formed inside the interlayer insulator and connected to a gate terminal 31.

In the terminal region 2, the N-type drift layer 11 and the P-type pillar layer 12 are not formed in all over the region but formed in a region within a certain range from the device region 1. A region formed in the peripheral region is composed of only the N-type drift layer 11 without the P-type pillar layer 12 formed therein. A high-concentration P-type region 25 serving as a field stop layer is formed in the surface of the surrounding region. A P⁺-type contact layer 27 is formed on the P-type region 25. Moreover, a field-stop electrode 28 is formed thereon. In addition, a field-stop conductive layer 29 is buried in the interlayer insulator 23, and is connected to the field-stop electrode 28.

The semiconductor device according to the present embodiment is configured such that the drift layer 14B in the terminal region 2 has a carrier lifetime controlled to have a value lower than ⅕ the carrier lifetime in the drift layer 14A in the device region 1.

Specifically, during a process for manufacturing the semiconductor device in the present embodiment, the drift layer 14B in the terminal region 2 is subjected to electron beam irradiation, proton irradiation, helium irradiation, or deposition of a heavy metal such as Pt on the surface, followed by thermal diffusion. As a result, the drift layer 14B in the terminal region 2 is given a higher resistance than the resistance determined by the impurity concentration. In addition, the carrier lifetime in the drift layer 14B in the terminal region 2 is controlled lower than the carrier lifetime in the drift layer 14A in the device region 1. Lowering the carrier lifetime in the drift layer 14B in the terminal region 2 in this way can enhance the avalanche ruggedness in the terminal region 2 without increasing the leakage current on reverse bias. In addition, it can improve the reverse recovery property on reverse recovery of the internal diode in the transistor and enhance the entire breakdown voltage in the semiconductor device.

Preferably, in the present embodiment the carrier lifetime in the terminal region 2 is not more than 1 [μs].

The present embodiment can be grasped from a different side. Namely, during a process for manufacturing the semiconductor device in the present embodiment, the drift layer 14B in the terminal region 2 is subjected to electron beam irradiation, proton irradiation, helium irradiation, or deposition of a heavy metal such as Pt on the surface, followed by thermal diffusion. As a result, the resistance in the drift layer 14B in the terminal region 2 is increased higher than the resistance in the device region 1. The resistance thus increased in the drift layer 14B in the terminal region 2 can enhance the entire breakdown voltage in the semiconductor device.

### Second Embodiment

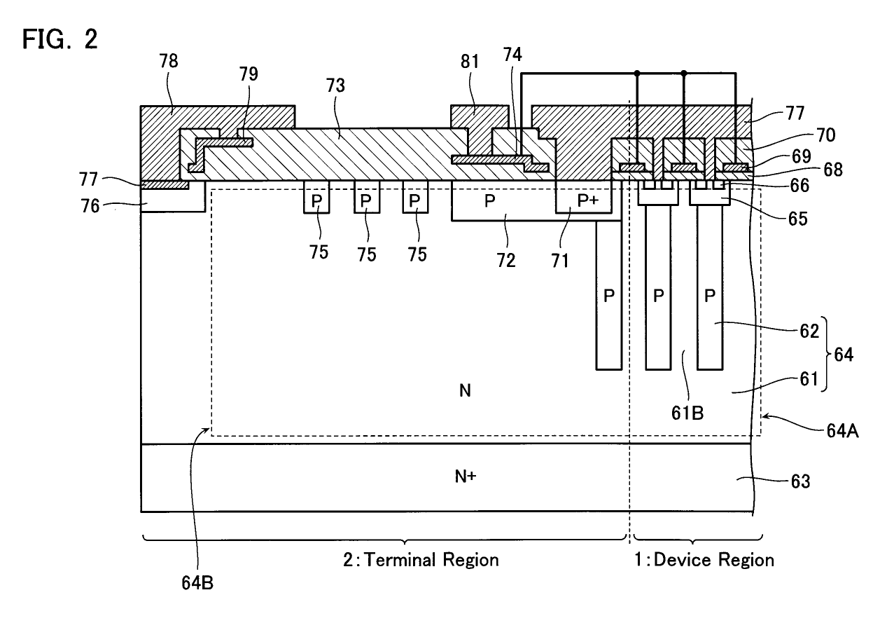

A second embodiment in the present invention is described below. A semiconductor device in the present embodiment is shown in FIG. 2. The semiconductor device in the present embodiment is a power semiconductor device, which comprises a device region 51 and a terminal region 52.

A transistor formed in the device region 51 has a superjunction structure, which includes an N-type drift layer 61, and a plurality of P-type pillar layer portions 62 formed in the N-type drift layer 61. In this embodiment, preferably, the P-type pillar layer 62 reaches the bottom of the N-type drift layer as shown in FIG. 2.

The N-type drift layer 61 has one surface (the lower surface in FIG. 2), on which an N⁺-type drain layer 63 is formed with a higher impurity concentration than the N-type drift layer 61. A drain electrode, not shown, is formed on the surface of the N⁺-type drain layer 63. In the present embodiment, a drift layer 64 includes the N-type drift layer 61 and the P-type pillar layer 62, and the drift layer 64 has a drift layer 64A formed in the device region 51 and a drift layer 64B formed in the terminal region 52.

In the N-type drift layer 61, the P-type pillar layer portions 62 are formed periodically as described above. An N-type drift layer portion 61 formed between a P-type pillar layer portion 62 and an adjacent P-type pillar layer portion 62 is specially referred to as an N-type drift layer portion 61B. In a region spread over the surface of the P-type pillar layer portion 62, a P-type base layer 65 is formed through ion implantation.

The P-type base layer 65 is formed in a stripe extending in the direction normal to the drawing. In the surface of each P-type base layer 65 thus formed, two N-type source layers 66 are formed extending in the direction normal to the drawing.

Further, a gate insulator 68 is formed on the surface of the N-type drift layer 61 sandwiched between a P-type base layer 65 and an adjacent P-type base layer 65, that is, a surface region between an N-type source layer 66 and an adjacent N-type source layer 66 with the N-type drift layer portion 61 sandwiched between the P-type base layers 65.

The gate insulator 68 is composed of silicon oxide with a thickness of about 0.1 [μs], for example. Further, a gate electrode 69 is formed on the gate insulator 68 and the gate electrode 19 is connected to other gate electrodes 69. An interlayer insulator 70 is formed on the gate electrodes.

In a region sandwiched between the gate electrode 69 and the gate electrode 69, a source electrode 67 is formed in contact with a P-type base layer 65 and two N-type source layers 66 formed in this P-type base layer 65. The source electrode 67 is formed to cover the interlayer insulator 70 and is connected to other source electrodes. The source electrode 67 is electrically insulated from the gate electrode 69 with the interlayer insulator 70 interposed therebetween.

On the other hand, in the terminal region 52, no P-type pillar layer portions 62 is formed other than a no-transistor configuring P-type pillar layer portion 62 formed in a region closest to the device region 51. Namely, in the terminal region 52 of the semiconductor device in this embodiment, no superjunction structure is formed. Therefore, in the present embodiment, the N-type drift layer 64B contained in the terminal region 52 has an impurity concentration controlled higher than the impurity concentration in the N-type pillar layer 61B in the device region 51.

In the terminal region 52, a P-type guard ring layer 72 is formed from the P-type pillar layer portion 62 provided in the terminal region 52 toward the terminal (in the opposite direction to the device region 51). A high-concentration P⁺-type region 71 is formed in the P-type guard ring layer 72. The P⁺-type region 71 has a surface, which comes in contact with the source electrode 67. Plural guard ring layer portions 75 are formed closer to the terminal than the P-type guard ring layer 72. A P-type region 76 serving as a field stop layer is formed in the surface of the region surrounding the plural guard ring layer portions 75. A P+-type contact layer 77 is formed on the P-type region 76. Moreover, a field-stop electrode 78 is formed thereon. In addition, a field-stop conductive layer 79 is buried in the interlayer insulator 73, and connected to the field-stop electrode 78. In the terminal region 52, an interlayer insulator 73 is formed over the surfaces of the P-type guard ring layer 72, the N-type drift layer 61 and the guard ring layer 75. A field plate 74 for connection to the gate electrode 69 is formed inside the interlayer insulator and connected to a gate terminal 81. The semiconductor device according to the present embodiment is configured such that the drift layer 64B in the terminal region 52 has a carrier lifetime controlled to have a value lower than ⅕ the carrier lifetime in the drift layer 64A in the device region 51.

Specifically, during a process for manufacturing the semiconductor device in the present embodiment, the drift layer 64B in the terminal region 52 is subjected to electron beam irradiation, proton irradiation, helium irradiation, or deposition of a heavy metal such as Pt on the surface, followed by thermal diffusion. As a result, the drift layer 64B in the terminal region 52 is given a higher resistance than the resistance determined by the impurity concentration. In addition, the carrier lifetime in the drift layer 64B in the terminal region 52 is controlled lower than the carrier lifetime in the drift layer 64A in the device region 51. Lowering the carrier lifetime in the drift layer 64B in the terminal region 52 in this way can enhance the avalanche ruggedness in the terminal region 2 without increasing the leakage current on reverse bias. In addition, it can improve the reverse recovery property on reverse recovery of the internal diode in the transistor and enhance the entire breakdown voltage in the semiconductor device.

Preferably, in the present embodiment the carrier lifetime in the terminal region 2 is not more than 1 [μs].

The present embodiment can be grasped from a different side. Namely, during a process for manufacturing the semiconductor device in the present embodiment, the drift layer 64B in the terminal region 52 is subjected to electron beam irradiation, proton irradiation, helium irradiation, or deposition of a heavy metal such as Pt on the surface, followed by thermal diffusion. As a result, the resistance in the drift layer 64B in the terminal region 52 is increased higher than the resistance in the device region 51. The resistance thus increased in the drift layer 64B in the terminal region 52 can enhance the entire breakdown voltage in the semiconductor device.

Thus, the breakdown voltage can be enhanced in the superjunction-structured MOS transistor without increasing the leakage current on reverse bias.

### [Production Methods in the Present Embodiment]

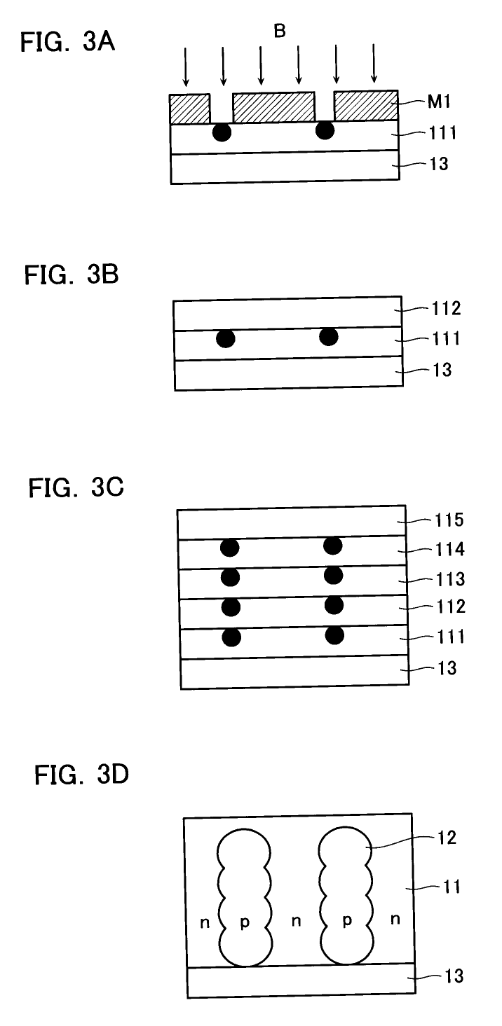

Methods for production of the drift layers 14 (the first embodiment) and 64 (the second embodiment) in the present embodiment are described next with reference to FIGS. 3-8.

The reference numerals in the first embodiment are used in the following description though either process is applicable in production of the semiconductor device in the second embodiment.

A first production method is described with reference to FIG. 3. First, an N-type epitaxial layer 111 to be turned into the N-type drift layer 111 is deposited thin on the N⁺-type drain layer 13 as shown in FIG. 3A. A mask M1 is formed on the N-type epitaxial layer 111. A photolithography process is applied to the mask M1 to form apertures in the shape of stripes at equal intervals. (The apertures are expressed in the shape of stripes having the longitudinal direction in the direction normal to the page in FIG. 3). With a mask of the mask M1, ions of boron (B) are implanted into the N-type epitaxial layer 111.

Thereafter, a further N-type epitaxial layer 112 to be turned into the N-type drift layer 11 is deposited thin on the N-type epitaxial layer 111 as shown in FIG. 3B. Then, the procedures shown in FIGS. 3A and 3B are repeated to deposit boron ion-implanted N-type epitaxial layers 111-115 in plural layers in the shape of stripes at equal intervals as shown in FIG. 3C.

Thereafter, the N-type epitaxial layers 111-115 are thermally processed to diffuse ion-implanted boron such that they are connected in the vertical direction. Thus, the P-type pillar layer portions 12 are formed as shown in FIG. 3D while the N-type drift layer 11 between the P-type pillar layer portions 12 forms the N-type pillar layer portions, resulting in the superjunction structure. FIG. 3 shows an example of ion implantation of a P-type impurity (such as boron) into the N-type epitaxial layer. In contrast, another available method comprises depositing a P-type epitaxial layer and implanting ions of an N-type impurity (phosphorous) therein.

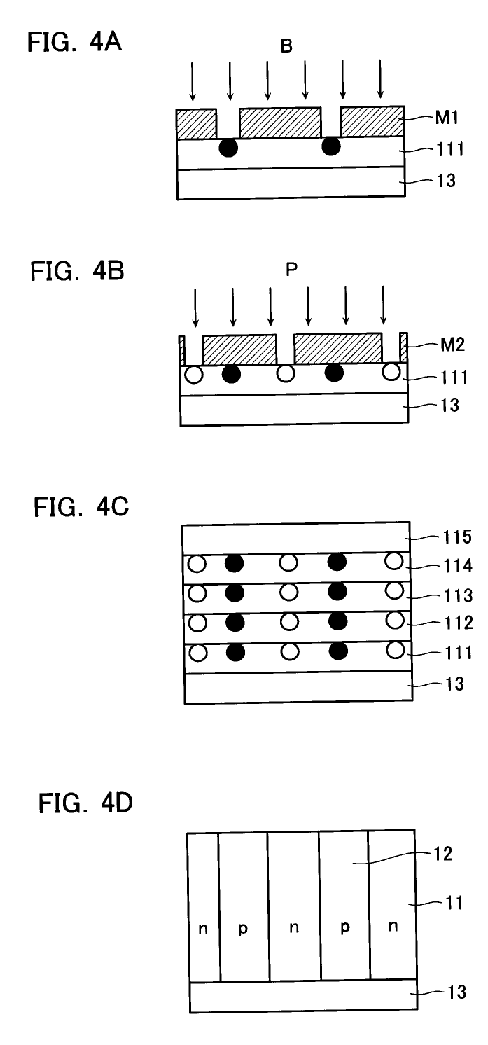

A second production method is described with reference to FIG. 4. First, an N-type epitaxial layer 111 to be turned into the N-type drift layer 11 is deposited thin on the N⁺-type drain layer 13 as shown in FIG. 4A. A mask M1 is formed on the N-type epitaxial layer 111. A photolithography process is applied to the mask M1 to form apertures in the shape of stripes at equal intervals. (The apertures are expressed in the shape of stripes having the longitudinal direction in the direction normal to the page in FIG. 4). With a mask of the mask M1, ions of boron (B) are implanted into the N-type epitaxial layer 111.

Subsequently, the mask M1 is peeled off and then a new mask M2 is formed with apertures in regions between the boron-implanted regions as shown in FIG. 4B. With a mask of the mask M2, ions of phosphorous (P) are implanted into the N-type epitaxial layer 111. Therefore, in the N-type epitaxial layer 111 the boron-implanted regions and the phosphorous-implanted regions are alternately formed in the lateral direction.

Thereafter, the steps of depositing thin epitaxial layers 112-115 and two types of ion implantation described in FIGS. 4A, 4B are repeated as shown in FIG. 4C. In addition, a thermal process is executed to diffuse the ion-implanted regions such that they are connected in the vertical direction. Thus completed is a drift layer having a superjunction structure including N-type pillar layer portions and P-type pillar layer portions 12 formed alternately as shown in FIG. 4D. The second production method can control the impurity concentration not only in the P-type pillar layer 12 but also in the N-type drift layer 11 independently. Accordingly, it is suitable for manufacturing the semiconductor device of the second embodiment.

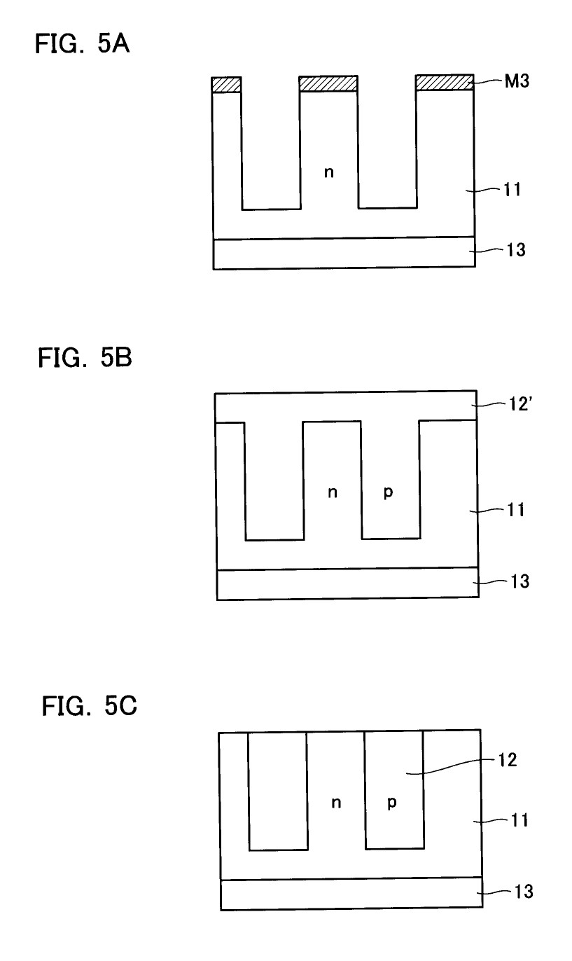

A third production method is described next with reference to FIG. 5A to 5C. As shown FIG. 5A, this method comprises applying a reactive ion etching (RIE) to the drift layer 11 with a mask M3 having apertures at equal intervals to form trenches; and depositing a P-type semiconductor layer 12′ on the N-type drift layer 11 including the inside of the trenches, as shown in FIG. 5B. A CMP (Chemical Mechanical Polishing) process is then used to remove the semiconductor layer 12′ from outside of the trenches, thereby forming a superjunction structure similarly.

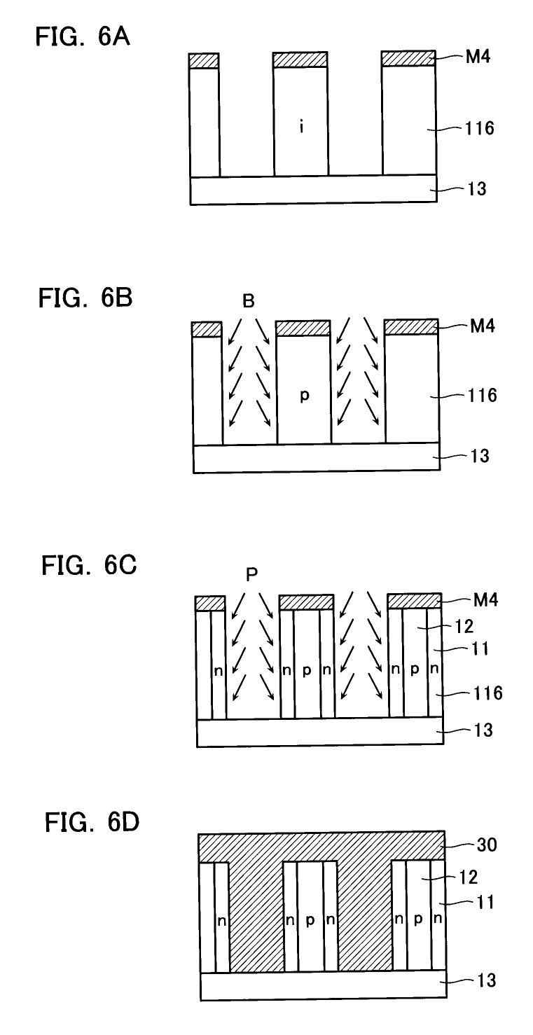

A fourth production method is described next with reference to FIG. 6A to 6D. This method comprises applying a RIE to an i-type epitaxial layer 116 formed on the n⁺-type drain layer 11 with a mask M4 having apertures at equal intervals to form trenches (FIG. 6A). Then, a rotational ion implantation process is used to implant ions of boron (B) into sides of the trenches in a slanting direction (FIG. 6B) to convert the i-type epitaxial layer 116 into a P-type layer.

Subsequently, a rotational ion implantation process is used to implant ions of phosphorous (P) into the same sides of the trenches at a lower acceleration voltage than the ion implantation of boron (FIG. 6C). Thus, formed in a mesa portion between trenches are three layers including the N-type pillar layer 11, the P-type pillar layer 12 and the N-type pillar layer 11 alternately. Thereafter, an insulator is disposed on the pillar layers 11, 12 including the inside of the trenches as shown in FIG. 6D. In the case of the sixth method, the impurity concentration can be controlled easily not only in the P-type pillar layer 12 but also in the N-type pillar layer 11. Accordingly, it is suitable for the production in the second embodiment. Ions of boron and arsenic may be implanted at the same time to form a similar N-type pillar layer 12 and a similar P-type pillar layer 12 through a thermal process in accordance with the difference in diffusion coefficient.

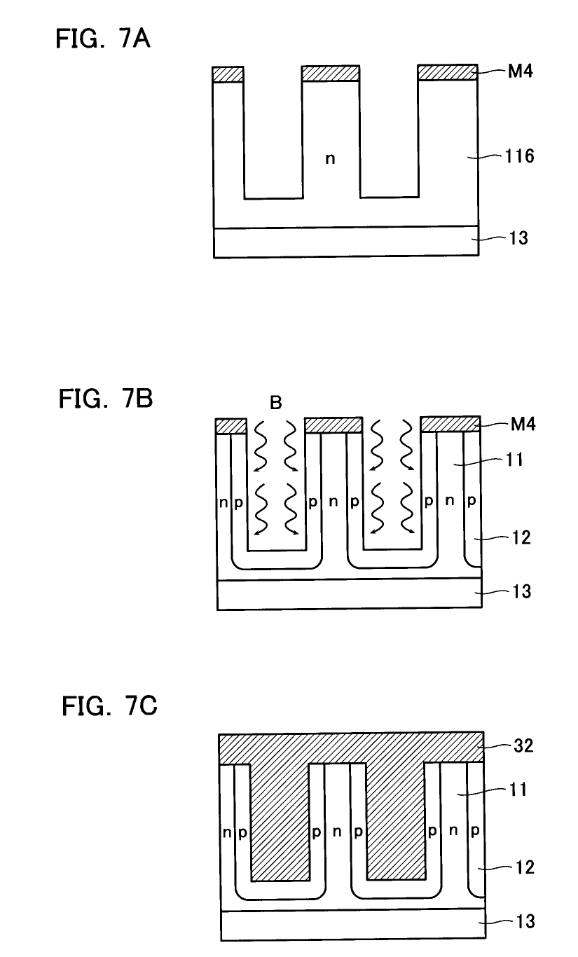

A fifth production method is described next with reference to FIG. 7A-7C. This method is same as the fourth production method in formation of trenches and ion implantation to the sides thereof. The fifth production method, however, uses a gaseous diffusion process in place of the rotation ion implantation, different from the fourth production method.

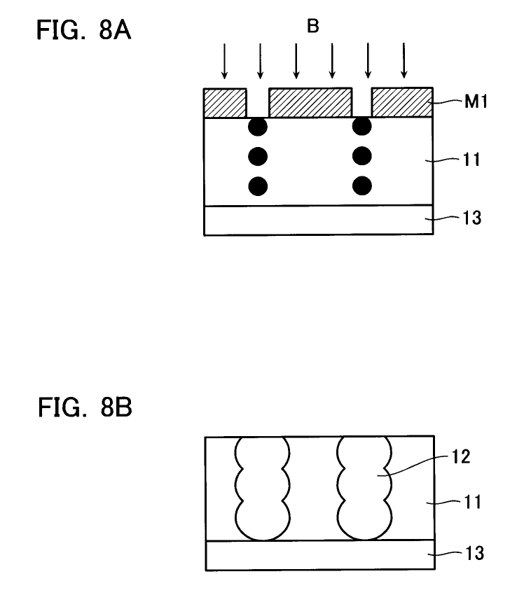

A sixth production method is described next with reference to FIG. 8A-8B. As shown in FIG. 8A, this method comprises forming a mask M1 having apertures at equal intervals on the N-type pillar layer 11; implanting ions through the apertures with varying the acceleration voltage; and conducting a heating process, thereby forming the P-type pillar layer 12. This method has no need for depositing a thin epitaxial layer, forming a mask thereon, and applying ion implantation repeatedly, thereby reducing the number of process steps.

As described above, plural elements disclosed in the above embodiments can be combined appropriately to form various inventions. For example, some elements can be deleted from all the elements shown in the embodiments. In addition, elements contained over different embodiments may be added or combined appropriately.

What is claimed is:

1. A semiconductor device having a drift layer with a pillar structure including first semiconductor layer portions of the first conduction type and second semiconductor layer portions of the second conduction type formed in pillars alternately and periodically on a semiconductor substrate, the device comprising:
a device region including a plurality of transistors composed of said first semiconductor layer portions and said second semiconductor layer portions and arrayed in the central area of said semiconductor device; and
a terminal region formed at the periphery of said device region without said transistors formed therein,
wherein said drift layer in said terminal region has a resistance controlled higher than the resistance of said drift layer in said device region and higher than the resistance determined by an impurity concentration.

2. The semiconductor device according to claim 1, wherein said drift layer in said terminal region has a carrier lifetime controlled lower than ⅕ the carrier lifetime in said drift layer in said device region.

3. The semiconductor device according to claim 2, wherein said carrier lifetime in said drift layer in said terminal region is not more than 1 [μs].

4. The semiconductor device according to claim 1, wherein said pillar structure is not formed in said drift layer in said terminal region.

5. The semiconductor device according to claim 4, wherein said drift layer in said terminal region has an impurity concentration controlled higher than the impurity concentration in said first semiconductor layer portions in said device region.

6. The semiconductor device according to claim 1, wherein said pillar structure is also formed in said drift layer in said terminal region.

7. The semiconductor device according to claim 1, wherein said drift layer in said terminal region is subjected to electron beam irradiation, proton irradiation, or helium irradiation such that it is given a higher resistance than the resistance determined by the impurity concentration.

8. The semiconductor device according to claim 1, wherein said drift layer in said terminal region is subjected to diffusion of a heavy metal such that it is given a higher resistance than the resistance determined by the impurity concentration.

9. The semiconductor device according to claim 1, further comprising a guard ring layer of the second conduction type formed in the surface of said drift layer in said terminal region in the vicinity of said device region and electrically connected to a main electrode of said transistor.

10. The semiconductor device according to claim 9, further comprising a resurf layer of the second conduction type formed adjacent to said guard ring layer in the surface of said drift layer in said terminal region and extending in the direction opposite to said device region.

11. A semiconductor device, comprising:
a device region including a plurality of transistors arrayed therein; and
a terminal region formed at the periphery of said device region without said transistors formed therein,
wherein said drift layer in said terminal region has a resistance controlled higher than the resistance of said drift layer in said device region and higher than the resistance determined by an impurity concentration,
wherein said drift layer in said terminal region has a carrier lifetime controlled lower than ⅕ the carrier lifetime in said drift layer in said device region.

12. The semiconductor device according to claim 11, wherein said carrier lifetime in said drift layer in said terminal region is not more than 1 [μs].

13. The semiconductor device according to claim 11, wherein said drift layer in said terminal region is subjected to electron beam irradiation, proton irradiation, or helium irradiation such that it is given a higher resistance than the resistance determined by the impurity concentration.

14. The semiconductor device according to claim 11, wherein said drift layer in said terminal region is subjected to diffusion of a heavy metal such that it is given a higher resistance than the resistance determined by the impurity concentration.

15. The semiconductor device according to claim 11, further comprising a guard ring layer of the second conduction type formed in the surface of said drift layer in said terminal region in the vicinity of said device region and electrically connected to a main electrode of said transistor.

16. The semiconductor device according to claim 15, further comprising a resurf layer of the second conduction type formed adjacent to said guard ring layer in the surface of said drift layer in said terminal region and extending in the direction opposite to said device region.
